(19) United States
(12) Patent Application Publication
(10) Pub. No.: US 2023/0314508 A1
(43) Pub. Date: Oct. 5, 2023

(54) IN-FIELD LATENT FAULT MEMORY AND LOGIC TESTING USING STRUCTURAL TECHNIQUES

(71) Applicant: Intel Corporation, Santa Clara, CA (US)

(72) Inventors: Elik Haran, Kfar Saba (IL); Nir Gerber, Haifa (IL); Tal Davidson, Petach Tikva M (IL); Wei Hu, Shanghai (CN); Nadav Levison, Herut (IL)

(73) Assignee: Intel Corporation, Santa Clara, CA (US)

(21) Appl. No.: 17/712,100

(22) Filed: Apr. 2, 2022

(51) Int. Cl. G01R 31/3183; G01R 31/3187; G01R 31/3185

(52) U.S. Cl. CPC G01R 31/318307; G01R 31/318597; G01R 31/3187

(57) ABSTRACT

Embodiments of apparatuses and methods for in-field testing of an integrated circuit (IC) are disclosed. In an embodiment, an apparatus includes an IC having circuitry to operate in a structural test mode, the structural test mode including a memory built-in self-test (MBIST) mechanism and an automatic test pattern generation (ATPG) mechanism; a microcontroller to enable and control the structural test mode during in-field operation of the IC; and a programmable logic device to support the ATPG mechanism.

### FIELD OF INVENTION

The field of invention relates generally to electronic products, and, more specifically, but without limitation, to reliability, availability, and serviceability of electronic products.

### BACKGROUND

An electronic product may be or may include an integrated circuit (IC) supporting a testability technique used during IC production testing, i.e., after fabrication of the IC and before the IC is used in a system. The testability technique may be structural (e.g., testing for defective memory and/or logical circuits in the IC), as opposed to functional (e.g., testing the overall operation of the IC). Examples of structural testability techniques include memory built-in self-test (MBIST), logic built-in self-test (LBIST), and automatic test pattern generation (ATPG).

### BRIEF DESCRIPTION OF THE DRAWINGS

The present invention is illustrated by way of example and not limitation in the figures of the accompanying drawings, in which like references indicate similar elements and in which:

FIG. 1 is a block diagram of an apparatus for in-field testing according to embodiments;

FIG. 2 is a block diagram of a programmable logic device in an apparatus for in-field testing according to embodiments;

FIG. 3 is a diagram of a method for in-field testing according to embodiments;

FIG. 4A is a block diagram illustrating both an in-order pipeline and a register renaming, out-of-order issue/execution pipeline according to embodiments;

FIG. 4B is a block diagram illustrating both an in-order architecture core and a register renaming, out-of-order issue/execution architecture core to be included in a processor according to embodiments;

FIG. 5 is a block diagram of a processor that may have more than one core, may have an integrated memory controller, and may have integrated graphics according to embodiments of the invention;

FIG. 6 is a block diagram of a system according to embodiments;

FIG. 7 is a block diagram of a first more specific system according to embodiments;

FIG. 8 is a block diagram of a second more specific system according to embodiments; and

FIG. 9 is a block diagram of a system-on-a-chip according to embodiments.

### DETAILED DESCRIPTION

In the following description, numerous specific details, such as component and system configurations, may be set forth in order to provide a more thorough understanding of the present invention. It will be appreciated, however, by one skilled in the art, that the invention may be practiced without such specific details. Additionally, some well-known structures, circuits, and other features have not been shown in detail, to avoid unnecessarily obscuring the present invention.

References to “one embodiment,” “an embodiment,” “example embodiment,” “various embodiments,” etc., indicate that the embodiment(s) described may include particular features, structures, or characteristics, but more than one embodiment may and not every embodiment necessarily does include the particular features, structures, or characteristics. Some embodiments may have some, all, or none of the features described for other embodiments. Moreover, such phrases are not necessarily referring to the same embodiment. When a particular feature, structure, or characteristic is described in connection with an embodiment, it is submitted that it is within the knowledge of one skilled in the art to effect such feature, structure, or characteristic in connection with other embodiments whether or not explicitly described.

As used in this description and the claims and unless otherwise specified, the use of the ordinal adjectives “first,” “second,” “third,” etc. to describe an element merely indicates that a particular instance of an element or different instances of like elements are being referred to, and is not intended to imply that the elements so described must be in a particular sequence, either temporally, spatially, in ranking, or in any other manner. Also, as used in descriptions of embodiments, a “/” character between terms may mean that an embodiment may include or be implemented using, with, and/or according to the first term and/or the second term (and/or any other additional terms).

As mentioned in the background section, an IC may support one or more structural techniques for use during production testing, i.e., after fabrication of the IC and before the IC is used in a system. Embodiments of the invention may be desired because they provide for structural techniques used during production testing, in a test mode and on a test machine (e.g., automatic test equipment (ATE)), to be leveraged for use during in-field testing of the IC (e.g., testing in a system or product ready for use or being used by a consumer or an end-user), without a test machine (e.g., ATE). Thus, embodiments may provide for ICs designed for production testing to be used in applications and/or to comply with safety standards (e.g., SIL-1 through SIL-3 levels for IEC 61508 for industrial products and ASIL-A through ASIL-D levels for ISO26262 for automotive products) that require in-field testing, without an expensive redesign of the IC. Such applications may include automotive, industrial, and other embedded products; and such in-field testing requirements may include checking for latent faults. A latent fault is a multiple-point fault, which may be a fault in both intended function and the corresponding monitoring safety mechanism, for example, an error in the data payload stored in memory or flowing on a bus, combined with an error in the data error detection mechanism. Embodiments may provide for detecting latent faults in-field, during the IC boot process and/or normal operation.

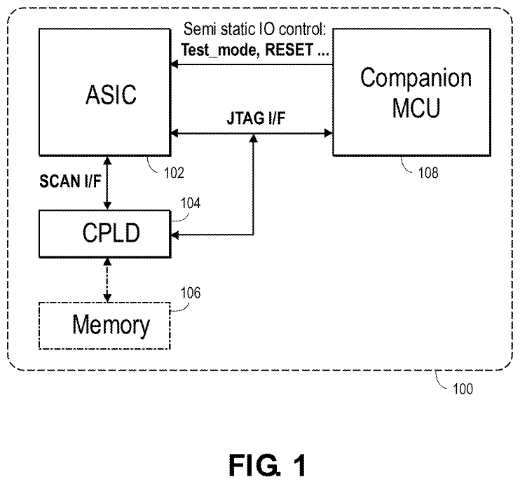

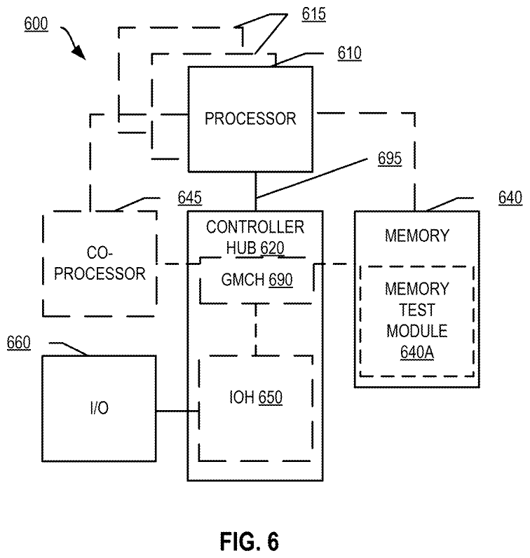

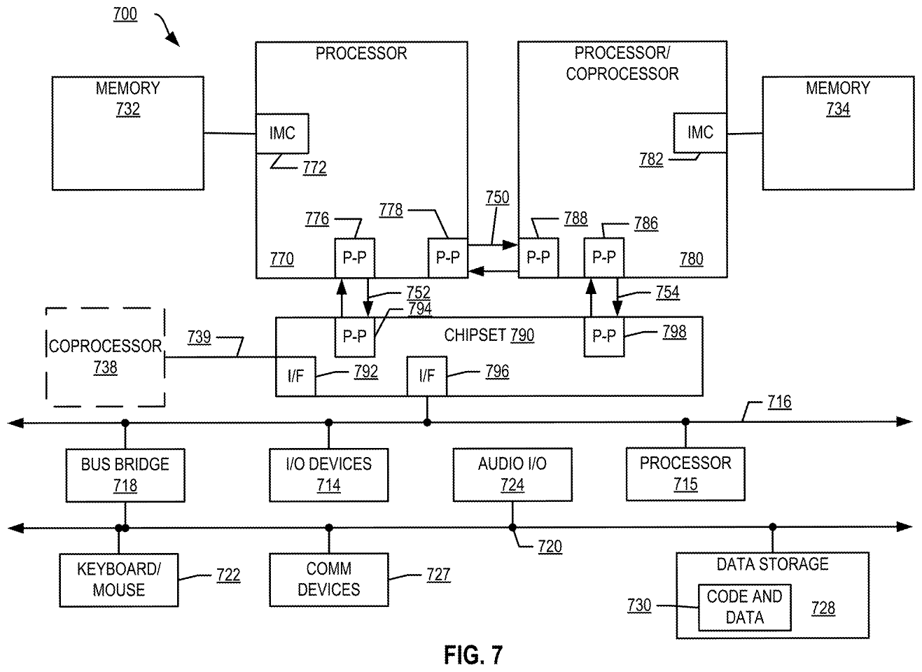

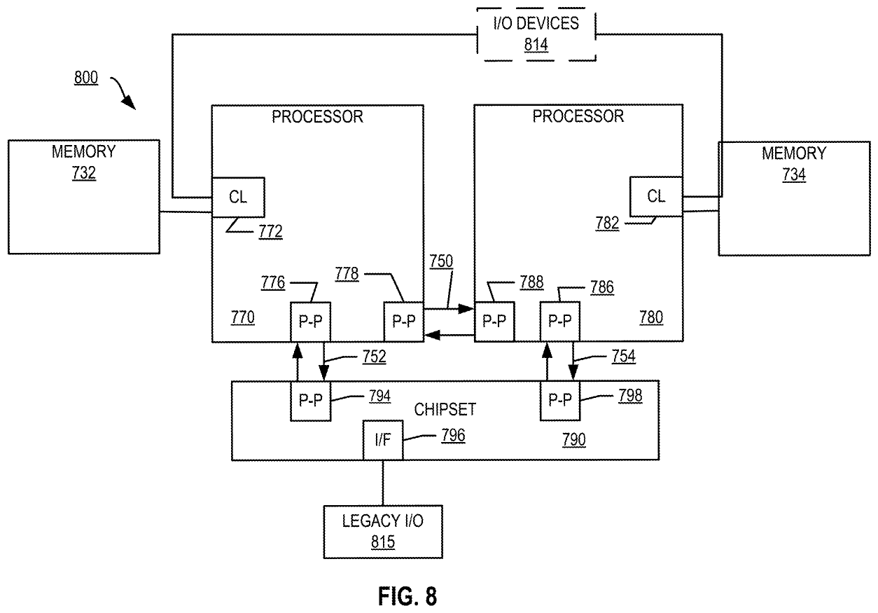

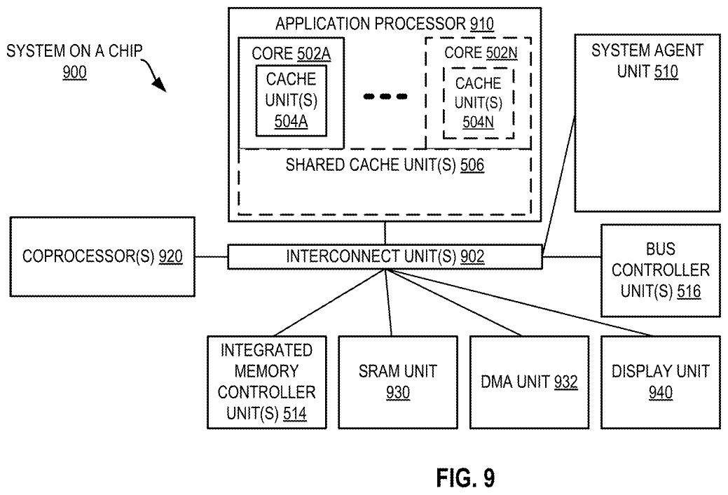

FIG. 1 is a block diagram of an in-field testing apparatus 100 according to embodiments. In-field testing apparatus 100 may be included in automotive, industrial, embedded, and information processing systems and other electronic products, such as system 600 in FIG. 6, system 700 in FIG. 7, system 800 in FIG. 8, or system-on-a-chip 900 in FIG. 9.

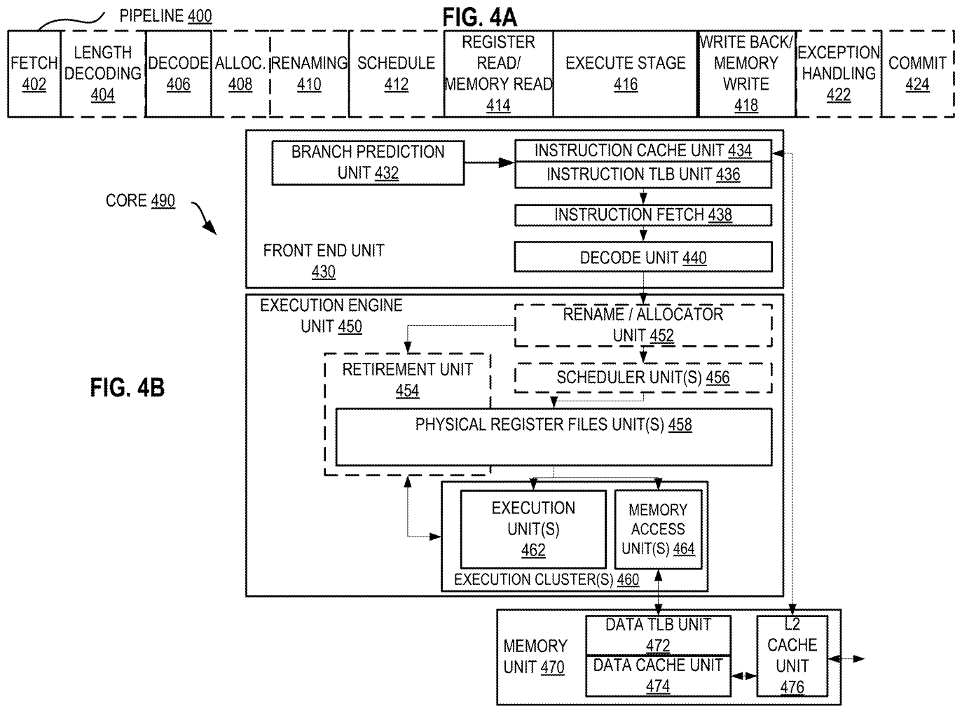

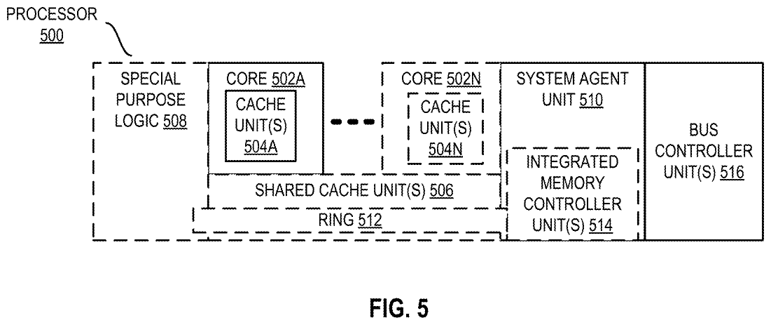

In-field testing apparatus 100, as shown in FIG. 1, includes IC 102, microcontroller unit (MCU) 108, and programmable logic device (PLD) 104, and may also include pattern memory 106. IC 102 is shown as application specific IC (ASIC) 102 but may represent any IC or system-on-a-chip (SoC) for which the reliability or safety level may be increased according to embodiments, such as a processor including core 490 in FIG. 4B, processor 500 in FIG. 5, any of processors 610-615 and co-processor 645 in FIG. 6, any of processors/co-processors 770, 780, 715, and 738 in FIG. 7, any of processor 770 or 780 in FIG. 8, and application processor 910 and co-processor 920 in FIG. 9. Each of IC 102, MCU 108, PLD 104, and memory 106 may be hardware components implemented in logic gates, memory cells, and/or any other type of circuitry.

ASIC 102 includes circuitry, designed for production testing, to provide one or more structural testability features and/or mechanisms (e.g., MBIST and ATPG). In embodiments, MCU 108 and PLD 104 may be used to enable these features/mechanisms during in-field use and/or operation.

MCU 108 is shown as companion MCU 108 but may also be referred to as a safety MCU or safety microcontroller. MCU 108 may represent any microcontroller designed, implemented, configured, and/or programmed to operate according to one or more embodiments, and may contain one or more central or other processing units, memory, embedded flash memory, programmable I/O peripherals, etc. for that purpose. MCU 108 may be connected to ASIC 102 to one or more semi-static input/output (I/O) control pins (e.g., test_mode, RESET) to provide input signals to ASIC 102 (as described below), and may also be connected to ASIC 102 through a joint test action group (JTAG) interface (I/F) or other test access port (TAP) of ASIC 102 to access one or more structural test mechanisms in ASIC 102 (as described below). These connections provide for MCU 108 to trigger ASIC 102 to transition between a test mode and an operational mode and to control the operation of structural tests in the field.

PLD 104, shown as complex PLD (CPLD) 104, may also be connected to ASIC 102 and MCU 108 through the JTAG interface, as well as being connected to ASIC 102 through a scan (e.g., boundary scan) interface. These connections provide for PLD 104 to support (e.g., enable and/or perform execution, acceleration, and/or analysis of results of) ATPG testing of ASIC 102 in the field (as described below). In embodiments, PLD 104 may represent any programmable peripheral component, such as a PLD, a CPLD, a field programmable gate array (FPGA), that may be connected to ASIC 102.

Apparatus 100 may also include pattern memory 106 (e.g., a non-volatile memory) connected to PLD 104 to store the ATPG test patterns for faster ATPG testing.

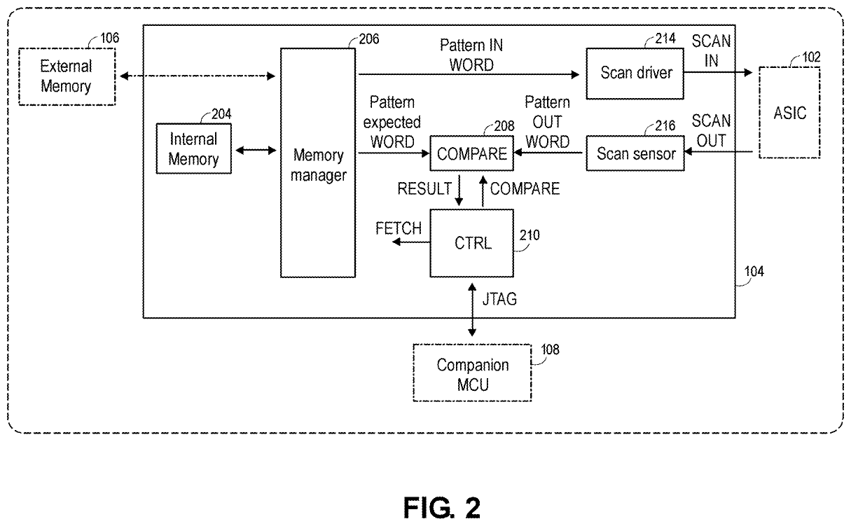

FIG. 2 is a block diagram of PLD 104 according to embodiments. As shown in FIG. 2, PLD 104 includes controller (CTRL) 210, memory manager 206, scan driver 214, scan sensor 216, comparator 208, and internal memory 204, each of which may be hardware units or blocks implemented in logic gates, memory cells, and/or any other type of circuitry.

Controller 210 is accessible by MCU 208 through the JTAG interface, and may include configuration registers, status fields, and functional state machines for ATPG control flow. Memory manager 206 may include logic to access internal memory 204 and/or external pattern memory 106 for reading scan patterns, which may be in word format. Controller 210 is to trigger this operation of memory manager 206 with a fetch transaction, which may specify an address and a number of data blocks to be read. In response, memory manager 206 is to provide each input pattern word to scan driver 214 and each corresponding expected pattern word to comparator 208.

Scan driver 214 is to receive each input pattern word and corresponding control signals from memory manager 206 and drives shift operation scan inputs to ASIC 102 through the scan interface. Scan sensor 216 is to receive shift operation scan outputs from ASIC 102 through the scan interface and provide each output pattern word to comparator 208.

Comparator 208 is to receive output pattern words from scan sensor 216 and corresponding expected pattern words from memory manager 206, and to compare the output pattern to the expected pattern (e.g., each pattern may be constructed from multiple words), then provide comparison results to controller 210. Comparison results may include a pass/fail result and, in some embodiments, metadata such as an indication of the location of a fault.

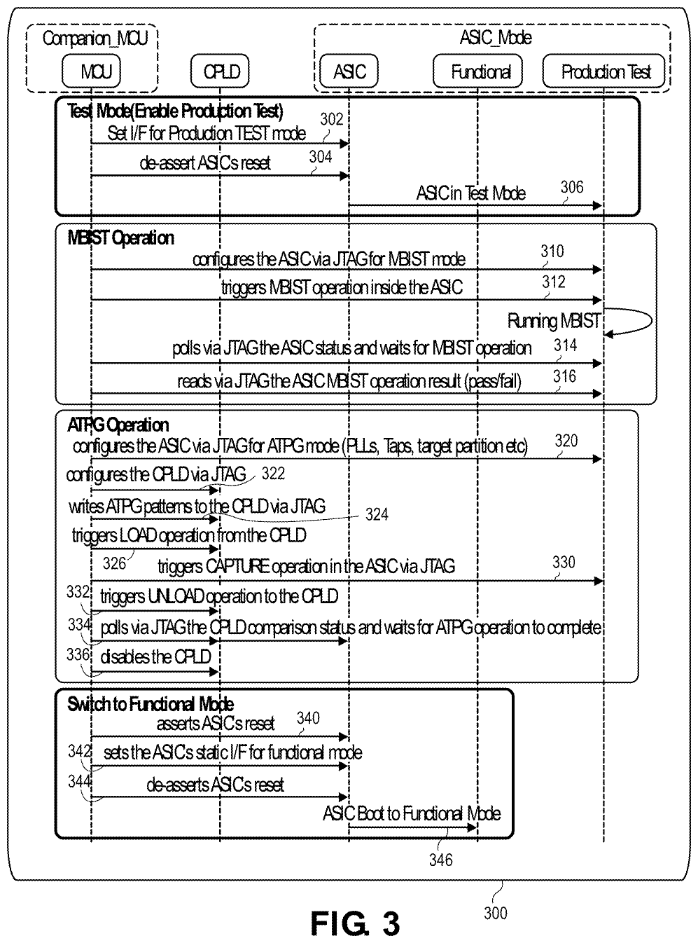

FIG. 3 is a diagram of method 300 for in-field testing according to embodiments. In embodiments, in-field testing (e.g., as shown in FIG. 3) may be performed during in-field booting of an IC (e.g., ASIC 102) preceding in-field operation of the IC, and/or during normal in-field operation of the IC (which may include booting and/or testing in a test mode or otherwise), thus increasing latent fault coverage. In various embodiments, different tests may be run during in-field booting and/or normal in-field operation, e.g., based on boot impact and/or interference time.

Actions (e.g., as represented by arrows in FIG. 3) in method embodiments may be performed by, initiated by, directed to, etc. an MCU (e.g., MCU 108), a PLD (e.g., PLD 104), and/or an IC (e.g., ASIC 102), as shown in FIG. 3.

Method 300 starts, as shown by arrow 302, by the MCU triggering the ASIC into production test mode (e.g., by asserting the ASIC's test mode and reset signals). As shown by arrow 304, the MCU de-asserts the ASIC's reset signal. As shown by arrow 306, the ASIC enters test mode.

Arrows 310, 312, 314, and 316 represent actions performed in connection with MBIST operation. Shown as 310, the MCU configures the ASIC, through the JTAG interface, for MBIST mode (e.g., configures phase-locked loops (PLLs), taps settings, and test parameters of the ASIC). Shown as 312, the MCU triggers MBIST operation in the ASIC, causing the ASIC to run MBIST. Shown as 314, the MCU polls, through the JTAG interface, the ASIC status while waiting for MBIST operation to complete. Shown as 316, the MCU reads, through the JTAG interface, the ASIC MBIST operation result (e.g., pass or fail). In response to the MBIST test passing, method 300 continues to arrow 320.

Arrows 320, 322, 324, 326, 330, 332, 334, and 336 represent actions performed in connection with ATPG operation. Shown as 320, the MCU configures the ASIC, through the JTAG interface, for ATPG mode (e.g., configures PLLs, taps, target partition). Shown as 322, the MCU configures the PLD through the JTAG interface. Shown as 324, the MCU writes one or more ATPG patterns to the PLD through the JTAG interface. Shown as 326, the MCU triggers an ATPG load operation (load the ATPG pattern(s)) to the PLD. Shown as 330, the MCU triggers, through the JTAG interface, an ATPG capture operation in the ASIC. Shown as 332, the MCU triggers an ATPG unload operation to the PLD. Shown as 334, the MCU polls, through the JTAG interface, the PLD for the status of the comparison of output pattern(s) versus expected pattern(s) while waiting for ATPG operation to complete. Shown as 336, the MCU disables the PLD. In response to the ATPG test passing, method 300 continues to arrow 340.

Shown as arrow 340, the MCU asserts the ASIC's reset signal. Shown as arrow 342, the MCU triggers the ASIC to transition into operational (functional) mode (e.g., by de-asserting the ASIC's test mode signal). Shown as arrow 344, the MCU de-asserts the ASIC's reset signal. Shown by arrow 306, the ASIC enters operational (functional) mode.

In various embodiments, actions shown in method 300 may be re-ordered and/or omitted; for example, arrow 324, representing the MCU writing the ATPG pattern(s) to the PLD, may be omitted in embodiments including non-volatile pattern memory external to the PLD (e.g., pattern memory 106).

### EXAMPLE EMBODIMENTS

In embodiments, an apparatus includes an IC having circuitry to operate in a structural test mode, the structural test mode including an MBIST mechanism and an ATPG mechanism; a microcontroller to enable and control the structural test mode during in-field operation of the IC; and a PLD to support the ATPG mechanism.

Any such embodiments may include any or any combination of the following aspects. The microcontroller may be connected to the IC through a plurality of control pins of the IC, the plurality of control pins including a test mode pin and a reset pin. The microcontroller may be connected to the IC through a JTAG interface. The PLD may be connected to the IC and the microcontroller through the JTAG interface. The PLD may be connected to the IC through a scan interface. The PLD may include a controller and a memory manager; wherein the controller is accessible by the microcontroller through the JTAG interface and is to trigger the memory manager to fetch one or more ATPG patterns from a memory. The memory may be within the PLD. The memory may be a non-volatile memory connected to the PLD. The PLD may include a scan driver, a scan sensor, and a comparator; wherein the memory manager is to provide an input pattern to the scan driver and a corresponding expected pattern to the comparator, the scan driver is to provide the input pattern to the IC through the scan interface, the scan sensor is to receive a corresponding output pattern from the IC through the scan interface, and the comparator is to compare the corresponding output pattern to the corresponding expected pattern.

In embodiments, an apparatus includes a memory manager; a controller, connected to a microcontroller, to trigger the memory manager to fetch one or more ATPG patterns from a memory; a scan driver; a scan sensor; and a comparator; wherein the microcontroller is to enable and control a structural test mode during in-field operation of an IC; and wherein the memory manager is to provide an input pattern to the scan driver and a corresponding expected pattern to the comparator, the scan driver is to provide the input pattern to the IC through a scan interface, the scan sensor is to receive a corresponding output pattern from the IC through the scan interface, and the comparator is to compare the corresponding output pattern to the corresponding expected pattern.

Any such embodiments may include any or any combination of the following aspects. The apparatus may be connected to the microcontroller through a JTAG interface. The apparatus may include the memory. The memory may be a non-volatile memory connected to the apparatus.

In embodiments, a method includes triggering, by a microcontroller, an IC to enter a structural test mode during in-field operation of the IC, the structural test mode including an MBIST mechanism and an ATPG mechanism; configuring, by the microcontroller, the IC for MBIST operation; triggering, by the microcontroller, MBIST testing of the IC; configuring, by the microcontroller, the IC for ATPG operation; triggering, by the microcontroller, ATPG testing of the IC; and triggering, by the microcontroller, the IC to enter a functional mode.

Any such embodiments may include any or any combination of the following aspects. The configuring of the IC for MBIST operation may be through a JTAG interface. The method may include configuring, by the microcontroller, a programmable logic device (PLD) to support the ATPG mechanism. The configuring of the IC for ATPG operation and the configuring of the PLD may be through the JTAG interface. The method may include triggering, by the microcontroller, an ATPG load operation. The method may include triggering, by the microcontroller, an ATPG capture operation. The method may include triggering, by the microcontroller, an ATPG unload operation.

In embodiments, an apparatus may include means for performing any function disclosed herein. In embodiments, an apparatus may include a data storage device that stores code that when executed by a hardware processor or controller causes the hardware processor or controller to perform any method or portion of a method disclosed herein. In embodiments, an apparatus may be as described in the detailed description. In embodiments, a method may be as described in the detailed description. In embodiments, a non-transitory machine-readable medium may store instructions that when executed by a machine causes the machine to perform any method or portion of a method disclosed herein. Embodiments may include any details, features, etc. or combinations of details, features, etc. described in this specification.

Example Core Architectures, Processors, and Computer Architectures

The following description and associated figures detail example architectures and systems to implement embodiments of the above.

Processor cores may be implemented in different ways, for different purposes, and in different processors. For instance, implementations of such cores may include: 1) a general purpose in-order core intended for general-purpose computing; 2) a high-performance general purpose out-of-order core intended for general-purpose computing; 3) a special purpose core intended primarily for graphics and/or scientific (throughput) computing. Implementations of different processors may include: 1) a CPU including one or more general purpose in-order cores intended for general-purpose computing and/or one or more general purpose out-of-order cores intended for general-purpose computing; and 2) a coprocessor including one or more special purpose cores intended primarily for graphics and/or scientific (throughput). Such different processors lead to different computer system architectures, which may include: 1) the coprocessor on a separate chip from the CPU; 2) the coprocessor on a separate die in the same package as a CPU; 3) the coprocessor on the same die as a CPU (in which case, such a coprocessor is sometimes referred to as special purpose logic, such as integrated graphics and/or scientific (throughput) logic, or as special purpose cores); and 4) a system on a chip that may include on the same die the described CPU (sometimes referred to as the application core(s) or application processor(s)), the above described coprocessor, and additional functionality. Example core architectures are described next, followed by descriptions of example processors and computer architectures.

Example Core Architectures

In-Order and Out-of-Order Core Block Diagram

FIG. 4A is a block diagram illustrating both an example in-order pipeline and an example register renaming, out-of-order issue/execution pipeline according to embodiments of the invention. FIG. 4B is a block diagram illustrating both an example embodiment of an in-order architecture core and an example register renaming, out-of-order issue/execution architecture core to be included in a processor according to embodiments of the invention. The solid lined boxes in FIGS. 4A-B illustrate the in-order pipeline and in-order core, while the optional addition of the dashed lined boxes illustrates the register renaming, out-of-order issue/execution pipeline and core. Given that the in-order aspect is a subset of the out-of-order aspect, the out-of-order aspect will be described.

In FIG. 4A, a processor pipeline 400 includes a fetch stage 402, a length decode stage 404, a decode stage 406, an allocation stage 408, a renaming stage 410, a scheduling (also known as a dispatch or issue) stage 412, a register read/memory read stage 414, an execute stage 416, a write back/memory write stage 418, an exception handling stage 422, and a commit stage 424.

FIG. 4B shows processor core 490 including a front-end unit 430 coupled to an execution engine unit 450, and both are coupled to a memory unit 470. The core 490 may be a reduced instruction set computing (RISC) core, a complex instruction set computing (CISC) core, a very long instruction word (VLIW) core, or a hybrid or alternative core type. As yet another option, the core 490 may be a special-purpose core, such as, for example, a network or communication core, compression engine, coprocessor core, general purpose computing graphics processing unit (GPGPU) core, graphics core, or the like.

The front-end unit 430 includes a branch prediction unit 432, which is coupled to an instruction cache unit 434, which is coupled to an instruction translation lookaside buffer (TLB) 436, which is coupled to an instruction fetch unit 438, which is coupled to a decode unit 440. The decode unit 440 (or decoder) may decode instructions, and generate as an output one or more micro-operations, micro-code entry points, microinstructions, other instructions, or other control signals, which are decoded from, or which otherwise reflect, or are derived from, the original instructions. The decode unit 440 may be implemented using various different mechanisms. Examples of suitable mechanisms include, but are not limited to, look-up tables, hardware implementations, programmable logic arrays (PLAs), microcode read only memories (ROMs), etc. In one embodiment, the core 490 includes a microcode ROM or other medium that stores microcode for certain macroinstructions (e.g., in decode unit 440 or otherwise within the front-end unit 430). The decode unit 440 is coupled to a rename/allocator unit 452 in the execution engine unit 450.

The execution engine unit 450 includes the rename/allocator unit 452 coupled to a retirement unit 454 and a set of one or more scheduler unit(s) 456. The scheduler unit(s) 456 represents any number of different schedulers, including reservations stations, central instruction window, etc. The scheduler unit(s) 456 is coupled to the physical register file(s) unit(s) 458. Each of the physical register file(s) units 458 represents one or more physical register files, different ones of which store one or more different data types, such as scalar integer, scalar floating point, packed integer, packed floating point, vector integer, vector floating point, status (e.g., an instruction pointer that is the address of the next instruction to be executed), etc. In one embodiment, the physical register file(s) unit 458 comprises a vector registers unit, a write mask registers unit, and a scalar registers unit. These register units may provide architectural vector registers, vector mask registers, and general-purpose registers. The physical register file(s) unit(s) 458 is overlapped by the retirement unit 454 to illustrate various ways in which register renaming and out-of-order execution may be implemented (e.g., using a reorder buffer(s) and a retirement register file(s); using a future file(s), a history buffer(s), and a retirement register file(s); using a register map and a pool of registers; etc.). The retirement unit 454 and the physical register file(s) unit(s) 458 are coupled to the execution cluster(s) 460. The execution cluster(s) 460 includes a set of one or more execution units 462 and a set of one or more memory access units 464. The execution units 462 may perform various operations (e.g., shifts, addition, subtraction, multiplication) and on various types of data (e.g., scalar floating point, packed integer, packed floating point, vector integer, vector floating point). While some embodiments may include a number of execution units dedicated to specific functions or sets of functions, other embodiments may include only one execution unit or multiple execution units that all perform all functions. The scheduler unit(s) 456, physical register file(s) unit(s) 458, and execution cluster(s) 460 are shown as being possibly plural because certain embodiments create separate pipelines for certain types of data/operations (e.g., a scalar integer pipeline, a scalar floating point/packed integer/packed floating point/vector integer/vector floating point pipeline, and/or a memory access pipeline that each have their own scheduler unit, physical register file(s) unit, and/or execution cluster—and in the case of a separate memory access pipeline, certain embodiments are implemented in which only the execution cluster of this pipeline has the memory access unit(s) 464). It should also be understood that where separate pipelines are used, one or more of these pipelines may be out-of-order issue/execution and the rest in-order.

The set of memory access units 464 is coupled to the memory unit 470, which includes a data TLB unit 472 coupled to a data cache unit 474 coupled to a level 2 (L2) cache unit 476. In one example embodiment, the memory access units 464 may include a load unit, a store address unit, and a store data unit, each of which is coupled to the data TLB unit 472 in the memory unit 470. The instruction cache unit 434 is further coupled to a level 2 (L2) cache unit 476 in the memory unit 470. The L2 cache unit 476 is coupled to one or more other levels of cache and eventually to a main memory.

By way of example, the example register renaming, out-of-order issue/execution core architecture may implement the pipeline 400 as follows: 1) the instruction fetch 438 performs the fetch and length decoding stages 402 and 404; 2) the decode unit 440 performs the decode stage 406; 3) the rename/allocator unit 452 performs the allocation stage 408 and renaming stage 410; 4) the scheduler unit(s) 456 performs the schedule stage 412; 5) the physical register file(s) unit(s) 458 and the memory unit 470 perform the register read/memory read stage 414; the execution cluster 460 perform the execute stage 416; 6) the memory unit 470 and the physical register file(s) unit(s) 458 perform the write back/memory write stage 418; 7) various units may be involved in the exception handling stage 422; and 8) the retirement unit 454 and the physical register file(s) unit(s) 458 perform the commit stage 424.

The core 490 may support one or more instructions sets (e.g., the x86 instruction set (with some extensions that have been added with newer versions); the MIPS instruction set of MIPS Technologies of Sunnyvale, CA; the ARM instruction set (with optional additional extensions such as NEON) of ARM Holdings of Sunnyvale, CA), including the instruction(s) described herein. In one embodiment, the core 490 includes logic to support a packed data instruction set extension (e.g., AVX1, AVX2), thereby allowing the operations used by many multimedia applications to be performed using packed data.

It should be understood that the core may support multithreading (executing two or more parallel sets of operations or threads), and may do so in a variety of ways including time sliced multithreading, simultaneous multithreading (where a single physical core provides a logical core for each of the threads that physical core is simultaneously multithreading), or a combination thereof (e.g., time sliced fetching and decoding and simultaneous multithreading thereafter such as in the Intel® Hyperthreading technology).

While register renaming is described in the context of out-of-order execution, it should be understood that register renaming may be used in an in-order architecture. While the illustrated embodiment of the processor also includes separate instruction and data cache units 434/474 and a shared L2 cache unit 476, alternative embodiments may have a single internal cache for both instructions and data, such as, for example, a Level 1 (L1) internal cache, or multiple levels of internal cache. In some embodiments, the system may include a combination of an internal cache and an external cache that is external to the core and/or the processor. Alternatively, all of the cache may be external to the core and/or the processor.

FIG. 5 is a block diagram of a processor 500 that may have more than one core, may have an integrated memory controller, and may have integrated graphics according to embodiments of the invention. The solid lined boxes in FIG. 5 illustrate a processor 500 with a single core 502A, a system agent 510, a set of one or more bus controller units 516, while the optional addition of the dashed lined boxes illustrates an alternative processor 500 with multiple cores 502A-N, a set of one or more integrated memory controller unit(s) 514 in the system agent unit 510, and special purpose logic 508.

Thus, different implementations of the processor 500 may include: 1) a CPU with the special purpose logic 508 being integrated graphics and/or scientific (throughput) logic (which may include one or more cores), and the cores 502A-N being one or more general purpose cores (e.g., general purpose in-order cores, general purpose out-of-order cores, a combination of the two); 2) a coprocessor with the cores 502A-N being a large number of special purpose cores intended primarily for graphics and/or scientific (throughput); and 3) a coprocessor with the cores 502A-N being a large number of general purpose in-order cores. Thus, the processor 500 may be a general-purpose processor, coprocessor, or special-purpose processor, such as, for example, a network or communication processor, compression engine, graphics processor, GPGPU (general purpose graphics processing unit), a high-throughput many integrated core (MIC) coprocessor (including 30 or more cores), embedded processor, or the like. The processor may be implemented on one or more chips. The processor 500 may be a part of and/or may be implemented on one or more substrates using any of a number of process technologies, such as, for example, BiCMOS, CMOS, or NMOS.

The memory hierarchy includes one or more levels of cache within the cores, a set or one or more shared cache units 506, and external memory (not shown) coupled to the set of integrated memory controller units 514. The set of shared cache units 506 may include one or more mid-level caches, such as level 2 (L2), level 3 (L3), level 4 (L4), or other levels of cache, a last level cache (LLC), and/or combinations thereof. While in one embodiment a ring-based interconnect unit 512 interconnects the integrated graphics logic 508 (integrated graphics logic 508 is an example of and is also referred to herein as special purpose logic), the set of shared cache units 506, and the system agent unit 510/integrated memory controller unit(s) 514, alternative embodiments may use any number of well-known techniques for interconnecting such units. In one embodiment, coherency is maintained between one or more cache units 506 and cores 502A-N.

In some embodiments, one or more of the cores 502A-N are capable of multi-threading. The system agent 510 includes those components coordinating and operating cores 502A-N. The system agent unit 510 may include for example a power control unit (PCU) and a display unit. The PCU may be or include logic and components needed for regulating the power state of the cores 502A-N and the integrated graphics logic 508. The display unit is for driving one or more externally connected displays.

The cores 502A-N may be homogenous or heterogeneous in terms of architecture instruction set; that is, two or more of the cores 502A-N may be capable of execution the same instruction set, while others may be capable of executing only a subset of that instruction set or a different instruction set.

Example Computer Architectures

FIGS. 6-9 are block diagrams of example computer architectures. Other system designs and configurations known in the arts for laptops, desktops, handheld PCs, personal digital assistants, engineering workstations, servers, network devices, network hubs, switches, embedded processors, digital signal processors (DSPs), graphics devices, video game devices, set-top boxes, micro controllers, cell phones, portable media players, handheld devices, and various other electronic devices, are also suitable. In general, a huge variety of systems or electronic devices capable of incorporating a processor and/or other execution logic as disclosed herein are generally suitable.

Referring now to FIG. 6, shown is a block diagram of a system 600 in accordance with one embodiment of the present invention. The system 600 may include one or more processors 610, 615, which are coupled to a controller hub 620. In one embodiment, the controller hub 620 includes a graphics memory controller hub (GMCH) 690 and an Input/Output Hub (IOH) 650 (which may be on separate chips); the GMCH 690 includes memory and graphics controllers to which are coupled memory 640 and a coprocessor 645; the IOH 650 couples input/output (I/O) devices 660 to the GMCH 690. Alternatively, one or both of the memory and graphics controllers are integrated within the processor (as described herein), the memory 640 and the coprocessor 645 are coupled directly to the processor 610, and the controller hub 620 in a single chip with the IOH 650.

The optional nature of additional processors 615 is denoted in FIG. 6 with broken lines. Each processor 610, 615 may include one or more of the processing cores described herein and may be some version of the processor 500.

The memory 640 may be, for example, dynamic random-access memory (DRAM), phase change memory (PCM), or a combination of the two. For at least one embodiment, the controller hub 620 communicates with the processor(s) 610, 615 via a multi-drop bus, such as a frontside bus (FSB), point-to-point interface such as QuickPath Interconnect (QPI), or similar connection 695.

In one embodiment, the coprocessor 645 is a special-purpose processor, such as, for example, a high-throughput MIC processor, a network or communication processor, compression engine, graphics processor, GPGPU, embedded processor, or the like. In one embodiment, controller hub 620 may include an integrated graphics accelerator.

There can be a variety of differences between the physical resources 610, 615 in terms of a spectrum of metrics of merit including architectural, microarchitectural, thermal, power consumption characteristics, and the like.

In one embodiment, the processor 610 executes instructions that control data processing operations of a general type. Embedded within the instructions may be coprocessor instructions. The processor 610 recognizes these coprocessor instructions as being of a type that should be executed by the attached coprocessor 645. Accordingly, the processor 610 issues these coprocessor instructions (or control signals representing coprocessor instructions) on a coprocessor bus or other interconnect, to coprocessor 645. Coprocessor(s) 645 accept and execute the received coprocessor instructions.

Referring now to FIG. 7, shown is a block diagram of a first more specific example system 700 in accordance with an embodiment of the present invention. As shown in FIG. 7, multiprocessor system 700 is a point-to-point interconnect system, and includes a first processor 770 and a second processor 780 coupled via a point-to-point interconnect 750. Each of processors 770 and 780 may be some version of the processor 500. In one embodiment of the invention, processors 770 and 780 are respectively processors 610 and 615, while coprocessor 738 is coprocessor 645. In another embodiment, processors 770 and 780 are respectively processor 610 and coprocessor 645.

Processors 770 and 780 are shown including integrated memory controller (IMC) units 772 and 782, respectively. Processor 770 also includes as part of its bus controller unit's point-to-point (P-P) interfaces 776 and 778; similarly, second processor 780 includes P-P interfaces 786 and 788. Processors 770, 780 may exchange information via a point-to-point (P-P) interface 750 using P-P interface circuits 778, 788. As shown in FIG. 7, IMCs 772 and 782 couple the processors to respective memories, namely a memory 732 and a memory 734, which may be portions of main memory locally attached to the respective processors.

Processors 770, 780 may each exchange information with a chipset 790 via individual P-P interfaces 752, 754 using point to point interface circuits 776, 794, 786, 798. Chipset 790 may optionally exchange information with the coprocessor 738 via a high-performance interface 792. In one embodiment, the coprocessor 738 is a special-purpose processor, such as, for example, a high-throughput MIC processor, a network or communication processor, compression engine, graphics processor, GPGPU, embedded processor, or the like.

A shared cache (not shown) may be included in either processor or outside of both processors, yet connected with the processors via P-P interconnect, such that either or both processors' local cache information may be stored in the shared cache if a processor is placed into a low power mode.

Chipset 790 may be coupled to a first bus 716 via an interface 796. In one embodiment, first bus 716 may be a Peripheral Component Interconnect (PCI) bus, or a bus such as a PCI Express bus or another third generation I/O interconnect bus, although the scope of the present invention is not so limited.

As shown in FIG. 7, various I/O devices 714 may be coupled to first bus 716, along with a bus bridge 718 which couples first bus 716 to a second bus 720. In one embodiment, one or more additional processor(s) 715, such as coprocessors, high-throughput MIC processors, GPGPU's, accelerators (such as, e.g., graphics accelerators or digital signal processing (DSP) units), field programmable gate arrays, or any other processor, are coupled to first bus 716. In one embodiment, second bus 720 may be a low pin count (LPC) bus. Various devices may be coupled to a second bus 720 including, for example, a keyboard and/or mouse 722, communication devices 727 and a storage unit 728 such as a disk drive or other mass storage device which may include instructions/code and data 730, in one embodiment. Further, an audio I/O 724 may be coupled to the second bus 720. Note that other architectures are possible. For example, instead of the point-to-point architecture of FIG. 7, a system may implement a multi-drop bus or other such architecture.

Referring now to FIG. 8, shown is a block diagram of a second more specific example system 800 in accordance with an embodiment of the present invention. Like elements in FIGS. 7 and 8 bear like reference numerals, and certain aspects of FIG. 7 have been omitted from FIG. 8 in order to avoid obscuring other aspects of FIG. 8.

FIG. 8 illustrates that the processors 770, 780 may include integrated memory and I/O control logic (“CL”) 772 and 782, respectively. Thus, the CL 772, 782 include integrated memory controller units and include I/O control logic. FIG. 8 illustrates that not only are the memories 732, 734 coupled to the CL 772, 782, but also that I/O devices 814 are also coupled to the control logic 772, 782. Legacy I/O devices 815 are coupled to the chipset 790.

Referring now to FIG. 9, shown is a block diagram of an SoC 900 in accordance with an embodiment of the present invention. Similar elements in FIG. 5 bear like reference numerals. Also, dashed lined boxes are optional features on more advanced SoCs. In FIG. 9, an interconnect unit(s) 902 is coupled to: an application processor 910 which includes a set of one or more cores 502A-N, which include cache units 504A-N, and shared cache unit(s) 506; a system agent unit 510; a bus controller unit(s) 516; an integrated memory controller unit(s) 514; a set or one or more coprocessors 920 which may include integrated graphics logic, an image processor, an audio processor, and a video processor; an static random access memory (SRAM) unit 930; a direct memory access (DMA) unit 932; and a display unit 940 for coupling to one or more external displays. In one embodiment, the coprocessor(s) 920 include a special-purpose processor, such as, for example, a network or communication processor, compression engine, GPGPU, a high-throughput MIC processor, embedded processor, or the like.

Embodiments of the mechanisms disclosed herein may be implemented in hardware, software, firmware, or a combination of such implementation approaches. Embodiments of the invention may be implemented as computer programs or program code executing on programmable systems comprising at least one processor, a storage system (including volatile and non-volatile memory and/or storage elements), at least one input device, and at least one output device.

Program code, such as code 730 illustrated in FIG. 7, may be applied to input instructions to perform the functions described herein and generate output information. The output information may be applied to one or more output devices, in known fashion. For purposes of this application, a processing system includes any system that has a processor, such as, for example; a digital signal processor (DSP), a microcontroller, an application specific integrated circuit (ASIC), or a microprocessor.

The program code may be implemented in a high-level procedural or object-oriented programming language to communicate with a processing system. The program code may also be implemented in assembly or machine language, if desired. In fact, the mechanisms described herein are not limited in scope to any particular programming language. In any case, the language may be a compiled or interpreted language.

One or more aspects of at least one embodiment may be implemented by representative instructions stored on a machine-readable medium which represents various logic within the processor, which when read by a machine causes the machine to fabricate logic to perform the techniques described herein. Such representations, known as “IP cores,” may be stored on a tangible, machine readable medium and supplied to various customers or manufacturing facilities to load into the fabrication machines that actually make the logic or processor.

Such machine-readable storage media may include, without limitation, non-transitory, tangible arrangements of articles manufactured or formed by a machine or device, including storage media such as hard disks, any other type of disk including floppy disks, optical disks, compact disk read-only memories (CD-ROMs), compact disk rewritables (CD-RWs), and magneto-optical disks, semiconductor devices such as read-only memories (ROMs), random access memories (RAMs) such as dynamic random access memories (DRAMs), static random access memories (SRAMs), erasable programmable read-only memories (EPROMs), flash memories, electrically erasable programmable read-only memories (EEPROMs), phase change memory (PCM), magnetic or optical cards, or any other type of media suitable for storing electronic instructions.

Accordingly, embodiments of the invention also include non-transitory, tangible machine-readable media containing instructions or containing design data, such as Hardware Description Language (HDL), which defines structures, circuits, apparatuses, processors and/or system features described herein. Such embodiments may also be referred to as program products.

In this specification, operations in flow diagrams may have been described with reference to example embodiments of other figures. However, it should be understood that the operations of the flow diagrams may be performed by embodiments of the invention other than those discussed with reference to other figures, and the embodiments of the invention discussed with reference to other figures may perform operations different than those discussed with reference to flow diagrams. Furthermore, while the flow diagrams in the figures show a particular order of operations performed by certain embodiments of the invention, it should be understood that such order is provided as an example (e.g., alternative embodiments may perform the operations in a different order, combine certain operations, overlap certain operations, etc.).

While the invention has been described in terms of several embodiments, those skilled in the art will recognize that the invention is not limited to the embodiments described, can be practiced with modification and alteration within the spirit and scope of the appended claims. The description is thus to be regarded as illustrative instead of limiting.

What is claimed is:

1. An apparatus comprising:
an integrated circuit (IC) having circuitry to operate in a structural test mode, the structural test mode including a memory built-in self-test (MBIST) mechanism and an automatic test pattern generation (ATPG) mechanism;
a microcontroller to enable and control the structural test mode during in-field operation of the IC;
a programmable logic device (PLD) to support the ATPG mechanism.

2. The apparatus of claim 1, wherein the microcontroller is connected to the IC through a plurality of control pins of the IC, the plurality of control pins including a test mode pin and a reset pin.

3. The apparatus of claim 2, wherein the microcontroller is also connected to the IC through a joint test action group (JTAG) interface.

4. The apparatus of claim 3, wherein the PLD is also connected to the IC and the microcontroller through the JTAG interface.

5. The apparatus of claim 4, wherein the PLD is also connected to the IC through a scan interface.

6. The apparatus of claim 5, wherein the PLD includes a controller and a memory manager; wherein the controller is accessible by the microcontroller through the JTAG interface and is to trigger the memory manager to fetch one or more ATPG patterns from a memory.

7. The apparatus of claim 6, wherein the memory is within the PLD.

8. The apparatus of claim 6, wherein the memory is a non-volatile memory connected to the PLD.

9. The apparatus of claim 6, wherein the PLD also includes a scan driver, a scan sensor, and a comparator; wherein the memory manager is to provide an input pattern to the scan driver and a corresponding expected pattern to the comparator, the scan driver is to provide the input pattern to the IC through the scan interface, the scan sensor is to receive a corresponding output pattern from the IC through the scan interface, and the comparator is to compare the corresponding output pattern to the corresponding expected pattern.

10. An apparatus comprising:
a memory manager;
a controller, connected to a microcontroller, to trigger the memory manager to fetch one or more automatic test pattern generation (ATPG) patterns from a memory;
a scan driver;
a scan sensor; and
a comparator;
wherein the microcontroller is to enable and control a structural test mode during in-field operation of an IC; and
wherein the memory manager is to provide an input pattern to the scan driver and a corresponding expected pattern to the comparator, the scan driver is to provide the input pattern to the IC through a scan interface, the scan sensor is to receive a corresponding output pattern from the IC through the scan interface, and the comparator is to compare the corresponding output pattern to the corresponding expected pattern.

11. The apparatus of claim 10, wherein the apparatus is connected to the microcontroller through a joint test action group (JTAG) interface.

12. The apparatus of claim 10, further comprising the memory.

13. The apparatus of claim 10, wherein the memory is a non-volatile memory connected to the apparatus.

14. A method comprising:
triggering, by a microcontroller, an integrated circuit (IC) to enter a structural test mode during in-field operation of the IC, the structural test mode including a memory built-in self-test (MBIST) mechanism and an automatic test pattern generation (ATPG) mechanism;
configuring, by the microcontroller, the IC for MBIST operation;
triggering, by the microcontroller, MBIST testing of the IC;
configuring, by the microcontroller, the IC for ATPG operation;
triggering, by the microcontroller, ATPG testing of the IC; and
triggering, by the microcontroller, the IC to enter a functional mode.

15. The method of claim 14, wherein the configuring of the IC for MBIST operation is through a joint test action group (JTAG) interface.

16. The method of claim 15, further comprising configuring, by the microcontroller, a programmable logic device (PLD) to support the ATPG mechanism.

17. The method of claim 16, wherein the configuring of the IC for ATPG operation and the configuring of the PLD are through the JTAG interface.

18. The method of claim 17, further comprising triggering, by the microcontroller, an ATPG load operation.

19. The method of claim 18, further comprising triggering, by the microcontroller, an ATPG capture operation.

20. The method of claim 19, further comprising triggering, by the microcontroller, an ATPG unload operation.
